(19) United States
(12) Patent Application Publication
(10) Pub. No.: US 2012/0161319 A1
(43) Pub. Date: Jun. 28, 2012

(54) BALL GRID ARRAY METHOD AND STRUCTURE

(75) Inventors: Yaohuang Huang, Singapore (SG); Yonggang Jin, Singapore (SG); Puay Gek Chua, Singapore (SG); How Yuan Hwang, Singapore (SG)

(73) Assignee: STMICROELECTRONICS PTE LTD., Singapore (SG)

(21) Appl. No.: 12/978,144

(22) Filed: Dec. 23, 2010

(51) Int. Cl. H01L 21/02; H01L 23/482

(52) U.S. Cl. 257/751; 438/653; 438/106; 257/E23.017; 257/E21.002

(57) ABSTRACT

A process for making an integrated circuit, a wafer level integrated circuit package or an embedded wafer level package includes forming copper contact pads on a substrate or substructure. The substructure may include devices and the contact pads may be used for forming electrical couplings to the devices. For example, copper plating may be applied to a substructure and the copper plating etched to form copper contact pads on the substructure. An etching process may be applied to remove barrier layer material on the substructure, such as adjacent to the copper pads. For example, a hydrogen peroxide etch may be applied to remove titanium-tungsten from a surface of the substructure. The pads are again etched to remove barrier layer etchant, byproducts and/or oxide from the pads. Contamination control steps may be performed, such as quick-dump-and-rinse (QDR) and spin-rinse-and-dry (SRD) processing.

### BACKGROUND

1. Technical Field

This disclosure generally relates to semiconductor devices, methods of making semiconductor devices, dies, wafer level packaging, embedded wafer level packaging, ball grid arrays and embedded wafer level ball grid arrays.

2. Description of the Related Art

Semiconductor devices may be produced by forming a plurality of components in or on one or more semiconductor wafers, substrates, dies, etc. Coupling pads may be formed on surfaces of the wafers, substrates or dies to facilitate packaging the semiconductor devices and/or electrically coupling the dies, wafers, etc., to other components of an electronic device or system. For example, to facilitate coupling a die, wafer, or embedded wafer level ball grid array into a semiconductor package coupled to a circuit board of an electronic system. Contact pads on surfaces of wafers, die, etc., may be used in connection with many types of semiconductor packages, including ball-grid array packages, die packages, wafer level packages, embedded wafer level packages, and embedded wafer level ball grid array packages.

### BRIEF SUMMARY

In an embodiment, a method comprises: forming a dielectric region on a substrate, the dielectric region having a plurality of channels in a first surface of the dielectric region; forming a barrier region of a first conductive material on the first surface of the dielectric region and on surfaces of the plurality of channels of the dielectric region; forming a conductive region of a second conductive material different from the first conductive material on the barrier region; removing part of the conductive region to form a plurality of conductive pads of the second conductive material in the plurality of channels; removing portions of the barrier region on the first surface of the dielectric region using a first etchant; and subsequently etching surfaces of the plurality of conductive pads of the second conductive material to remove the first etchant from surfaces of the plurality of conductive pads. In an embodiment, the method further comprises forming a plurality of components in a substructure of the substrate, wherein forming the dielectric region comprises forming a dielectric layer on the substructure and forming channels through the dielectric layer to components of the plurality of components. In an embodiment, the first conductive material comprises titanium tungsten and the second conductive material comprises copper. In an embodiment, removing part of the conductive region to form a plurality of conductive pads of the second conductive material in the plurality of channels comprises etching the conductive region. In an embodiment, the first etchant comprises hydrogen peroxide. In an embodiment, etching surfaces of the plurality of conductive pads of the second conductive material comprises removing traces of the hydrogen peroxide and hydrogen peroxide byproducts from surfaces of the plurality of conductive pads. In an embodiment, the method further comprises assembling an integrated circuit package including the substrate. In an embodiment, the plurality of conductive pads of the second conductive material comprise a plurality of conductive pads of a semiconductor package ball-grid array. In an embodiment, subsequently etching surfaces of the plurality of conductive pads of the second conductive material comprises using at least one etchant selected from the group including: cupric chloride; ferric chloride; ammonium sulfate; ammonia; nitric acid; and hydrochloric acid. In an embodiment, the method further comprises: subsequently forming a plurality of conductive regions of a third conductive material on at least some of the plurality of conductive pads of the second conductive material, wherein the third conductive material is different from the second conductive material. In an embodiment, the plurality of conductive regions of a third conductive material comprise a plurality of solder balls. In an embodiment, the third conductive material comprises at least one of nickel and gold.

In an embodiment, a method comprises: forming a barrier region of a first conductive material on a substrate; forming a first plurality of conductive regions of a second conductive material, each region of the first plurality of conductive regions of the second conductive material having a first surface on the barrier region and a second surface opposite of the first surface; etching portions of the barrier region between the first plurality of conductive regions of the second conductive material using a first etchant; and subsequently etching at least the second surfaces of the first plurality of conductive regions of the second conductive material to remove the first etchant from at least the second surfaces of the first plurality of conductive regions. In an embodiment, the barrier region comprises forming a barrier layer having a plurality of channels and forming the first plurality of conductive regions of the second conductive material comprises forming conductive regions of the second conductive material in the plurality of channels of the barrier layer. In an embodiment, the first conductive material comprises titanium tungsten and the second conductive material comprises copper. In an embodiment, the first plurality of conductive regions of the second conductive material comprise a plurality of conductive pads. In an embodiment, the first plurality of conductive regions of the second conductive material comprise a plurality of conductive traces. In an embodiment, the first plurality of conductive regions of the second conductive material comprise a plurality of conductive pads and a plurality of conductive traces. In an embodiment, the method further comprises forming a second plurality of conductive regions on at least some of the second surfaces of the first plurality of conductive regions. In an embodiment, the second plurality of conductive regions comprise the second conductive material. In an embodiment, at least some of the second plurality of conductive regions comprise redistribution layers.

In an embodiment, a semiconductor device comprises: a wafer having a plurality of die; and a first plurality of conductive regions separated by at least one dielectric region, each of the first plurality of conductive regions having: a barrier region on the wafer; and a copper region having at least a first surface on the barrier region and a second surface opposite of the first surface, wherein an oxidation thickness of the second surface of the copper region is less than 100 nanometers. In an embodiment, the first plurality of conductive regions comprise a plurality of conductive pads of a ball-grid array. In an embodiment, the oxidation thickness of the second surface of the copper region is less than 10 nanometers. In an embodiment, the first plurality of conductive regions comprise a plurality of redistribution layers and the semiconductor device further comprises: a second plurality of conductive regions on at least some of the plurality of redistribution layers. In an embodiment, the second plurality of conductive regions comprise copper bonding pads.

### BRIEF DESCRIPTION OF THE SEVERAL VIEWS OF THE DRAWINGS

FIG. 1 is a partial cross-sectional view of an embodiment of a die during a manufacturing process.

FIG. 2 is a partial cross-sectional view of an embodiment of a die during a manufacturing process.

FIG. 3 is a partial cross-sectional view of an embodiment of a die during a manufacturing process.

FIG. 4 is a partial cross-sectional view of an embodiment of a die during a manufacturing process.

FIG. 5 is a partial cross-sectional view of an embodiment of a die during a manufacturing process.

FIG. 6 is a partial cross-sectional view of an embodiment of a die during a manufacturing process.

FIG. 7 is a partial cross-sectional view of an embodiment of a die during a manufacturing process.

FIG. 8 illustrates an embodiment of a method of manufacturing a semiconductor device.

FIG. 9 is a partial cross-sectional view of an embodiment of an embedded wafer level ball grid array during a manufacturing process.

FIG. 10 is a partial cross-sectional view of an embodiment of an embedded wafer level ball grid array during a manufacturing process.

FIG. 11 is a partial cross-sectional view of an embodiment of an embedded wafer level ball grid array during a manufacturing process.

FIG. 12 is a partial cross-sectional view of an embodiment of an embedded wafer level ball grid array during a manufacturing process.

FIG. 13 is a partial cross-sectional view of an embodiment of an embedded wafer level ball grid array during a manufacturing process.

FIG. 14 is a partial cross-sectional view of an embodiment of an embedded wafer level ball grid array during a manufacturing process.

FIG. 15 is a partial cross-sectional view of an embodiment of an embedded wafer level ball grid array during a manufacturing process.

FIG. 16 is a partial cross-sectional view of an embodiment of an embedded wafer level ball grid array during a manufacturing process.

FIG. 17 is a partial cross-sectional view of an embodiment of an embedded wafer level ball grid array during a manufacturing process.

### DETAILED DESCRIPTION

In the following description, certain details are set forth in order to provide a thorough understanding of various embodiments of devices, methods and articles. However, one of skill in the art will understand that other embodiments may be practiced without these details. In other instances, well-known structures and methods associated with, for example, substrates, integrated circuits, wafer level packaging, embedded wafer level packaging, ball grid arrays, embedded wafer level ball grid arrays, die, and fabrication processes, such as salicide processes, alloy deposition processes, thermal treatment processes, etching, annealing, film deposition and removal, processors, etc., have not been shown or described in detail in some figures to avoid unnecessarily obscuring descriptions of the embodiments.

Unless the context requires otherwise, throughout the specification and claims which follow, the word “comprise” and variations thereof, such as “comprising,” and “comprises,” are to be construed in an open, inclusive sense, that is, as “including, but not limited to.”

Reference throughout this specification to “one embodiment,” or “an embodiment” means that a particular feature, structure or characteristic described in connection with the embodiment is included in at least one embodiment. Thus, the appearances of the phrases “in one embodiment,” or “in an embodiment” in various places throughout this specification are not necessarily referring to the same embodiment, or to all embodiments. Furthermore, the particular features, structures, or characteristics may be combined in any suitable manner in one or more embodiments to obtain further embodiments.

The headings are provided for convenience only, and do not interpret the scope or meaning of this disclosure or the claims.

The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not necessarily intended to convey any information regarding the actual shape of particular elements, and have been selected solely for ease of recognition in the drawings. Geometric references are not intended to refer to ideal embodiments. For example, a rectilinear-shaped feature or element does not mean that a feature or element has a geometrically perfect rectilinear shape.

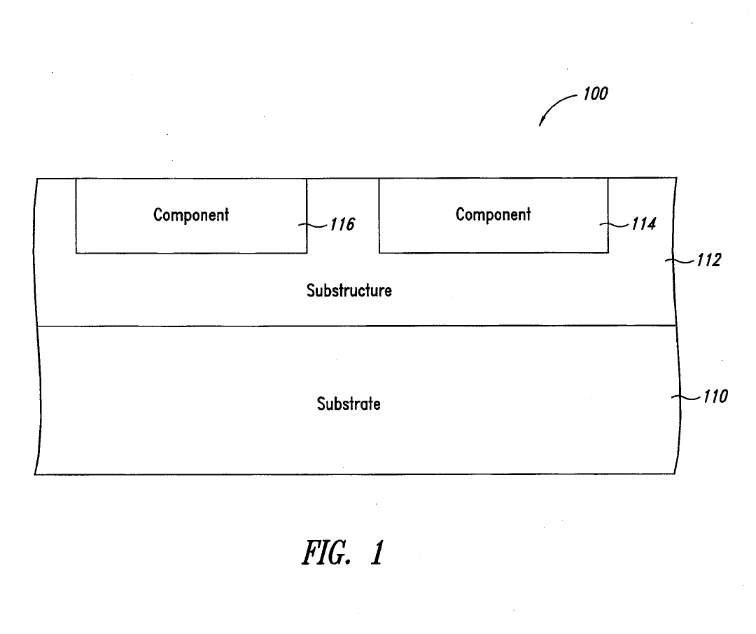

FIGS. 1 through 7 are partial cross-sectional views of an embodiment of a die 100 during various stages of an embodiment of a manufacturing process. All or portions of the manufacturing process may occur in a vacuum. The die 100 has a substrate 110 with an optional substructure 112. The substrate 110 may be formed, for example, of monocrystalline semiconductor material such as silicon. Regions or portions or layers of the substrate 110 and/or the substructure 112 may be doped with a desired conductivity type, for example, either P-type or N-type. The substructure 112 may comprise, for example, integrated circuits, electrodes, passive components, active components, mechanical components, etc., and may comprise multiple layers, sub-layers and regions forming multiple components and substructures. While the illustrated embodiments are described in terms of regions formed using layers and processing, such as etching, etc. of layers, layers or regions positioned or formed in other manners (such as through the use of sacrificial or substructure regions, punching, etc.) may be employed. As illustrated, the substructure 112 has a first component 114 and a second component 116, which may be, for example, an integrated circuit (which may itself comprise components such as active component, passive components, electrodes, etc.), an active component, such as a transistor, etc., a passive component, such as a resistor, capacitor, etc., an electrode, etc. Typically, a die may comprise many components in a substructure 112, and each component may comprise one or more regions of the substrate and/or sub-structure.

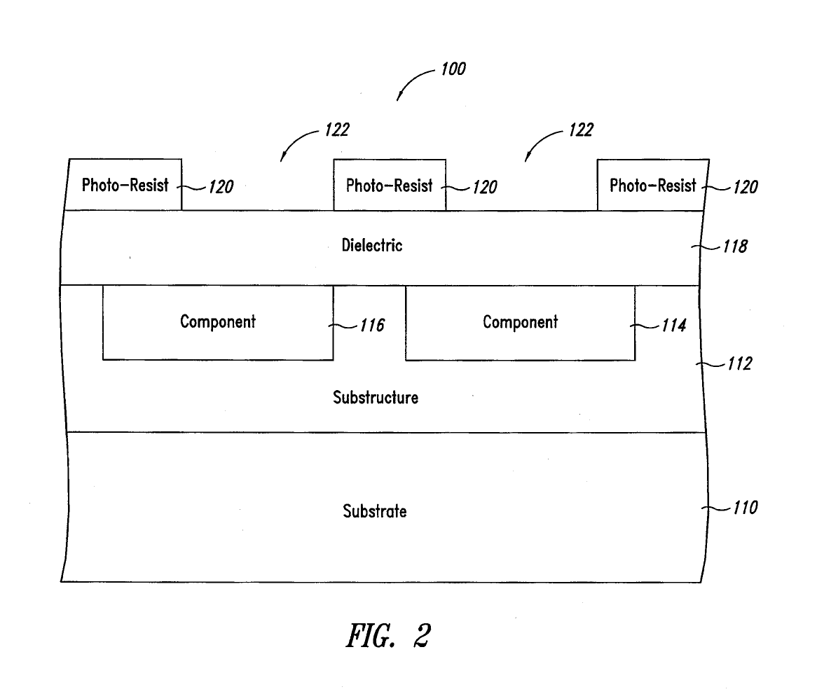

FIG. 2 shows an embodiment of a die 100 after a dielectric layer 118 and a photo-resist layer 120 have been positioned or formed on the substructure 112. The dielectric layer 118 may comprise, for example, silicon dioxide, etc. As illustrated the photo-resist layer 120 has been exposed to light to form channels 122 in the photo-resist layer 120. For ease of illustration, only two channels are shown. Typically, hundreds or thousands of channels may be formed.

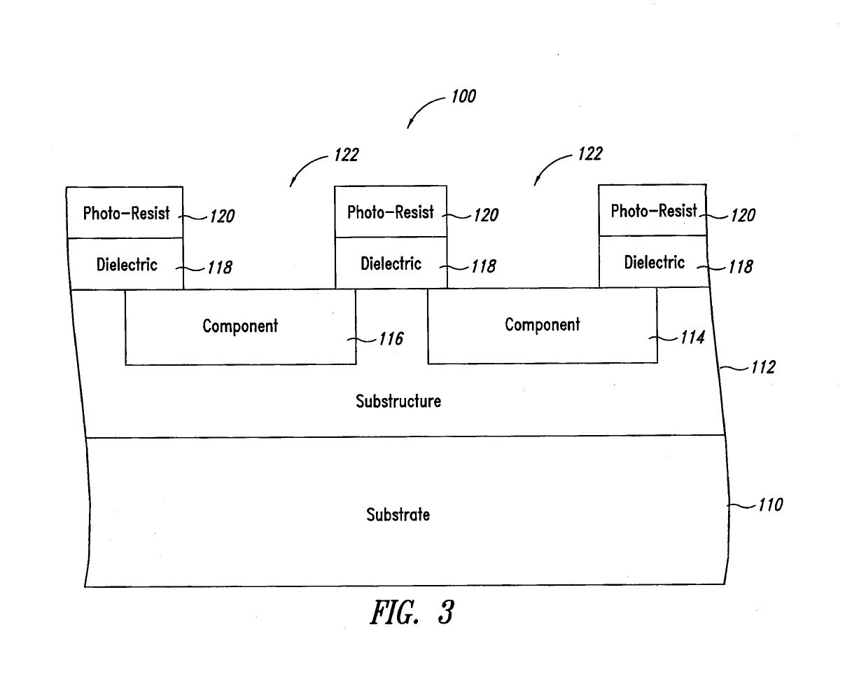

FIG. 3 shows of an embodiment of a die 100 after an etching process has been applied to remove portions of the dielectric layer 118. As illustrated, the etching process extends the channels 122 to the components 114, 116 of the die 100. The etching process may be controlled so as to form channels extending through the dielectric layer 118 to the substructure 112, to form channels for conductive traces on the dielectric layer 118, and or combinations thereof. For ease of illustration, a single channel 122 is shown extending to a respective component 114, 116. Multiple channels extending to a component also may be formed. For example, in embodiments hundreds or thousands of channels may be formed extending through the dielectric layer 118 to a component, such as an integrated circuit, etc.

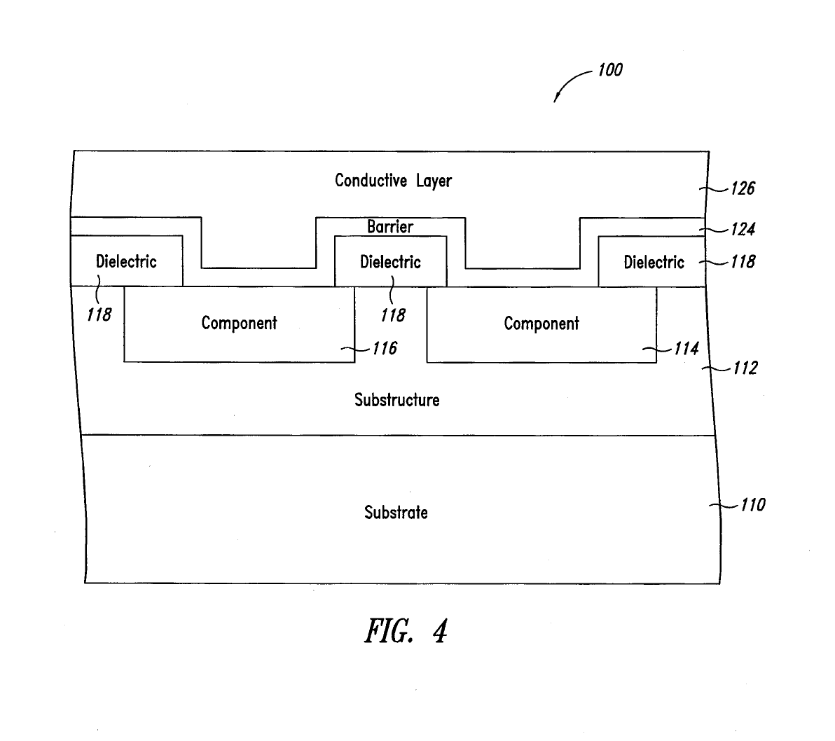

FIG. 4 shows an embodiment of a die 100 after the layer of photo-resist 120 has been removed and a barrier layer 124 of a first conductive material has been formed, positioned or applied on the dielectric layer 118. For example, a barrier layer 124 of titanium, titanium tungsten, etc., may be formed using plating, chemical vapor deposition, physical vapor deposition, reflow, etc. Typically, a barrier layer may be very thin, on the order of a few microns. In addition, a conductive layer 126 of a second conductive material has been formed, positioned or applied to the barrier layer 124. For example, a layer of copper, aluminum, other metals, metal alloys, etc., may be applied using plating, chemical vapor deposition, physical vapor deposition, reflow, etc. The barrier layer 124 is conductive and, for example, may reduce penetration of or contamination caused by the conductive layer 126 in regions of, for example, the components 114, 116 of the substructure 112.

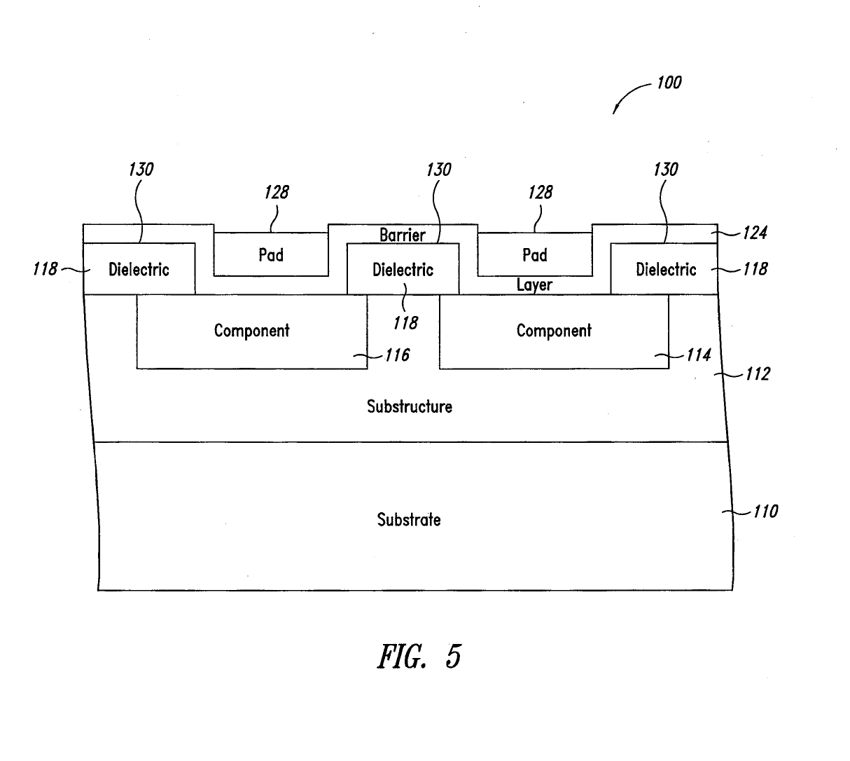

FIG. 5 shows an embodiment of a die 100 after a process has been applied to remove part of the conductive layer 126 to form a plurality of conductive regions 128 of the second conductive material. In the discussion, the conductive regions referred to are pads, but other conductive regions may be formed, such as traces, and the plurality of conductive regions may include combinations of conductive regions, such as pads and traces, and traces coupled to pads, etc. Wet or dry etching methods or chemical-mechanical polishing, etc., may be employed, for example. In an embodiment, the second conductive material may be copper, etc., and the etching process may employ, for example, cupric chloride, ferric chloride, ammonium sulfate, ammonia, nitric acid, hydrochloric acid, hydrogen peroxide, etc.

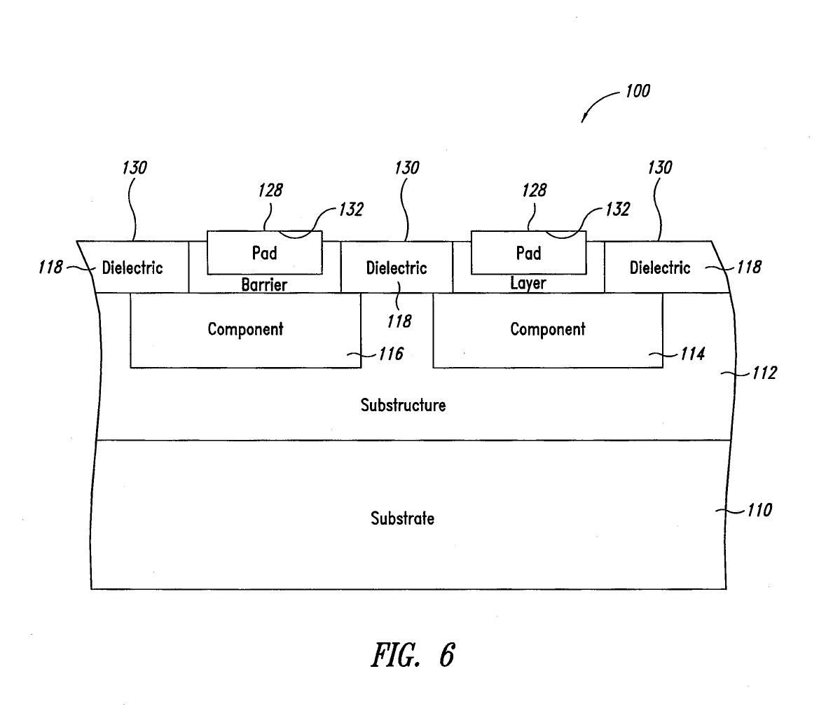

FIG. 6 shows an embodiment of a die 100 after an etching process has been employed to remove portions of the barrier layer 124 on a surface 130 of the dielectric layer 118. A chemical etching process using an etchant, such as hydrogen peroxide, etc., may be employed. Although embodiments of the conductive layer removal process of FIG. 5 and embodiments of the barrier layer etching of FIG. 6 may occur separately, in some embodiments removal of part of the conductive layer and etching of the barrier later may occur at least to some extent simultaneously. For example, hydrogen peroxide employed to etch the barrier layer 124 may also etch the conductive layer 126 and/or the conductive regions 128 to some extent.

The etching processes used to etch the barrier layer 124, whether performed after or at least partially simultaneously with etching of the conductive layer, can leave traces of the etchant of the barrier layer and byproducts thereof on surfaces of the die 100 which may directly or indirectly contribute to oxidation or contamination of surfaces 132 of the plurality of conductive pads 128. For example, traces of an etchant, such as hydrogen peroxide used to etch the barrier layer 124 may be left on the surfaces 132 of the conductive pads 128, and may, during subsequent thermal treatment, processes, etc., disassociate and become water and O₂. The O₂ may react with the conductive regions, for example, with copper, to form an oxide on the surfaces 132 of the conductive regions or pads 128. For example, even though processing typically would occur in a clean room, byproducts of the barrier layer etching process can result in the formation of oxide layers, such as copper oxide, on the surfaces 132 of the pads 128 on the order of a few micrometers in thickness during subsequent processing steps.

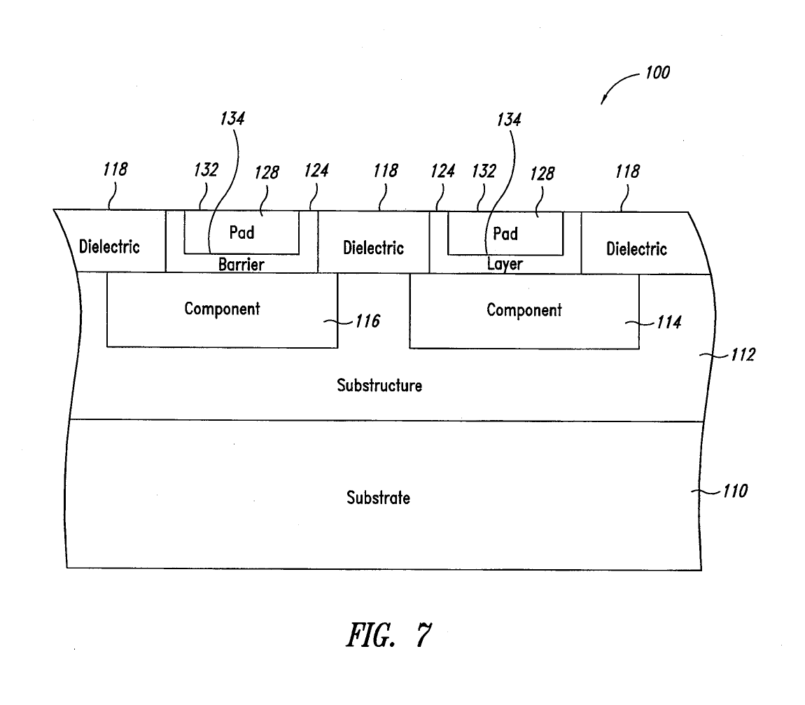

FIG. 7 shows a die 100 after a conductive region 128 etching process is employed subsequent to the barrier layer etching process. The conductive region etching process employed may be selected so as to remove undesirable chemicals or residue on the surfaces 132 of the regions or pads 128, preventing the formation of oxide on the regions 128, such as copper-oxide, etc., due to the presence of the barrier layer etchant and/or byproducts of the barrier layer etchant during subsequent processing. For example, the use of hydrogen peroxide may be avoided in the conductive region etching process of the conductive regions or pads 128. As illustrated, the conductive regions or pads 128 have a second surface 134 opposite of the first surface 132 and in contact with the barrier layer 124. After the subsequent etching of the first surfaces 132 of the conductive regions 128, the first and second surfaces 132, 134 of the conductive regions may have a substantially similar oxidation level. Quick-dump-rinse and spin-rinse dry procedures and other processing may then be applied in some embodiments. For example, a quick-dump-rinse in ionized water, etc., may be followed by a spin-rinse dry process.

As previously noted, multiple pads 128 may be electrically coupled to a component, such as the component 114. The pads may have a thickness on the order of, for example, 10,000 Angstroms. The etching of the conductive regions 128 after the etching of the barrier layer 124 substantially reduces the formation of oxides on the conductive regions or pads 128 during subsequent processing due to the presence of barrier layer etchant or byproducts thereof on the conductive regions or pads. While some oxidation may occur even in a clean room environment, the etching of the conductive regions to remove barrier layer etchant or byproducts thereof from the pads can reduce the formation of oxide during subsequent processing to a thickness on the order of, for example, a few nanometers or less.

Embodiments of the die 100 may be employed, for example, in wafer level packaging, embedded wafer level packaging, ball grid arrays and embedded wafer level ball grid arrays. The conductive regions, for example, may serve as conductive pads and/or traces for wafer level packaging, embedded wafer level packaging, ball grid arrays, embedded wafer level ball grid arrays, etc.

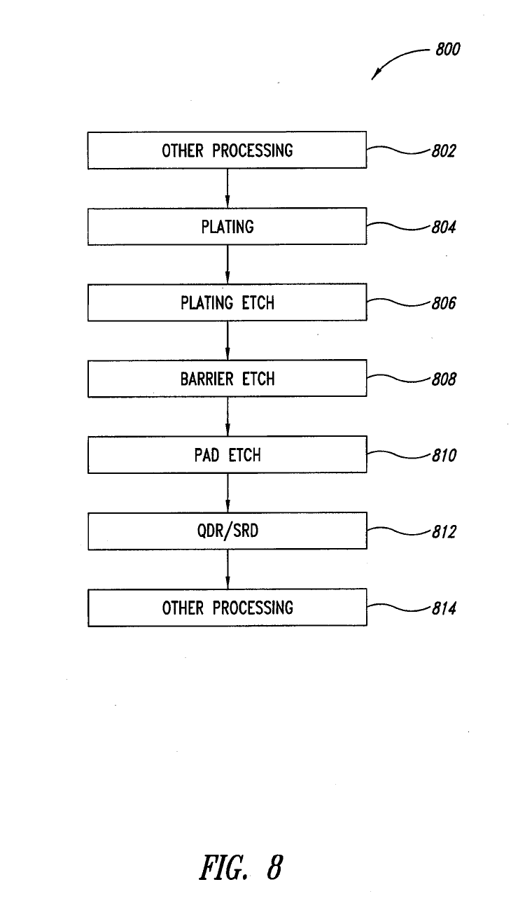

FIG. 8 shows an embodiment of a method 800 of manufacturing semiconductor devices. For convenience, method 800 will be described with reference to the die 100 illustrated in FIGS. 1 through 7. Other processing 802 may occur before the illustrated acts. At act 804 at least part of a surface of a die is plated with a barrier material, for example with titanium tungsten, and with a conductive material, for example with copper, etc. For example, a barrier layer 124 of titanium tungsten and a conductive layer 126 of copper may be applied. At act 806, the plating is etched to produce a plurality of conductive regions of the conductive material on the die. For example, to produce the regions 128 of FIG. 5. At 808, the barrier material is etched to remove portions of the barrier material between the plurality of conductive regions. For example, hydrogen peroxide may be used to remove titanium tungsten on surfaces 130 of the die between the plurality of conductive regions 128. At act 810, the conductive regions or pads are etched again to remove traces and/or byproducts of the barrier material etchant, such as hydrogen peroxide, from surfaces of the conductive regions. For example, the surfaces 132 on the pads 128 may be etched to remove hydrogen peroxide or byproducts of hydrogen peroxide. At 812, cleaning processes such as quick-dump-rinse and/or spin-rinse-dry processes, etc., are performed. At act 814, other manufacturing steps may occur, such as forming or positioning other conductive materials on the pads 128. For example, positioning nickel or gold coatings on the pads and/or applying solder balls to the pads, separating a wafer into a plurality of dies, forming embedded wafer level ball grid arrays, etc.

Embodiments of methods of manufacturing semiconductor devices such as die may employ additional steps, layers, regions and processes, etc., may omit steps, layers, regions, processes, etc., and may perform steps and processes in various orders. For example, photo-resist processes, stop-etch layers or regions or sacrificial layers and regions may be employed in some embodiments. In another example, in some embodiments another material may be applied to the plurality of conductive regions 128 during subsequent processing to avoid leaving the conductive regions exposed. For example, metal or metal alloys such as copper, nickel, gold, other metals and alloys, etc., may be applied to one or more or conductive regions such as conductive pads. For example, a layer of nickel, for example on the order of 300 to 800 Angstroms in thickness, and a layer of gold, on the order of 30 Angstroms in thickness, may be applied to the conductive regions or pads 128 in some embodiments. In another example, solder balls may be applied to one or more conductive regions, such as copper pads, etc., and may be applied after the application of additional layers to the conductive regions 128. In another example, additional conductive regions may be formed or applied, such as one or more build-up regions and one or more redistribution layers, which may comprise, for example, copper.

FIGS. 9 through 17 illustrate partial cross-section views of embodiments of a embedded wafer level ball grid array 200 during various stages of embodiments of manufacturing processes. FIG. 9 shows an embodiment of an array 200 having a wafer body 202 and a die 204 with a contact pad 206, such as a contact pad for a component (see component 114 of FIG. 1). For each of illustration, only one die 204 and only one contact pad 206 are illustrated. Typically, an array, such as the array 200, would have multiple dies, with each die having multiple contact pads.

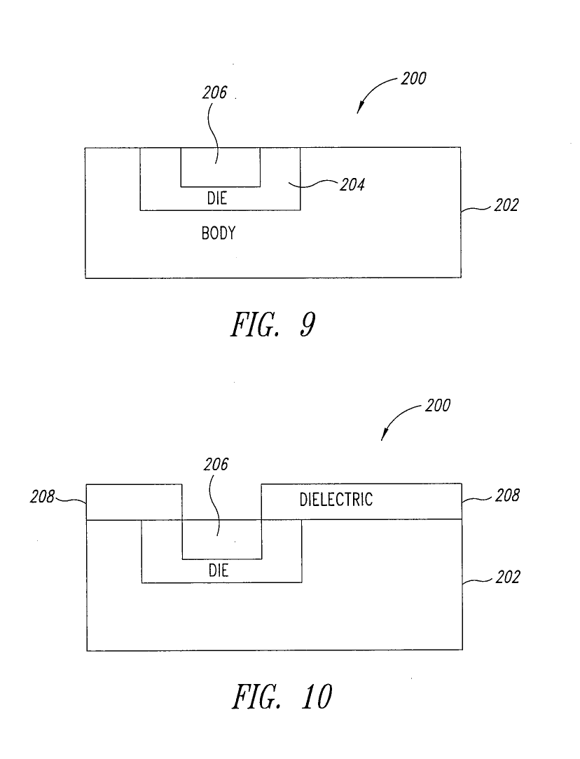

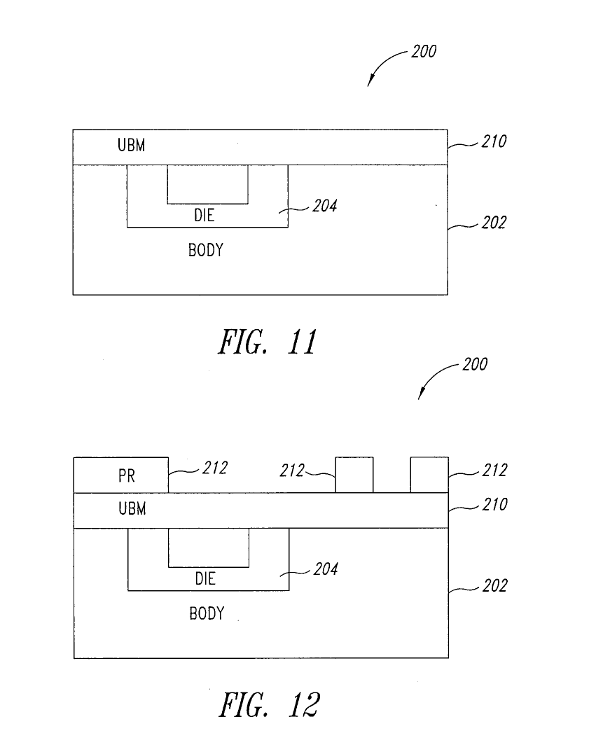

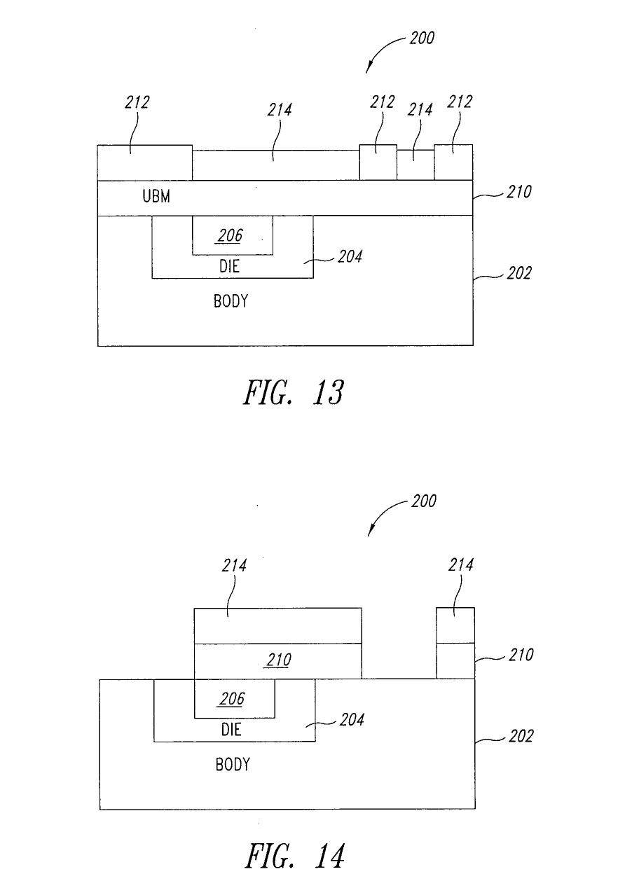

FIG. 10 shows an embodiment of an array 200 after an optional dielectric material 208 has been deposited or formed. FIG. 11 shows an embodiment of an array 200 after an under-bump metallization or barrier region 210 has been applied. For example, titanium, titanium tungsten, etc., may be employed. As illustrated in the embodiment of FIG. 11, the optional dielectric material 208 has been omitted. FIG. 12 shows an embodiment of an array 200 after a photo-resist has been applied and patterned. FIG. 13 shows an embodiment of an array 200 after a conductive plating 214 is applied. For example, copper plating, etc., may be performed, to form contact pads, redistribution layers and combinations thereof. FIG. 14 shows an embodiment of an array 200 with the photo-resist striped and the barrier material between regions of the conductive plating etched using an etchant, such as hydrogen peroxide, etc. The conductive plating is then etched to remove the photo-resist stripant and/or the barrier material etchant and byproducts thereof from surfaces of the conductive plating 214.

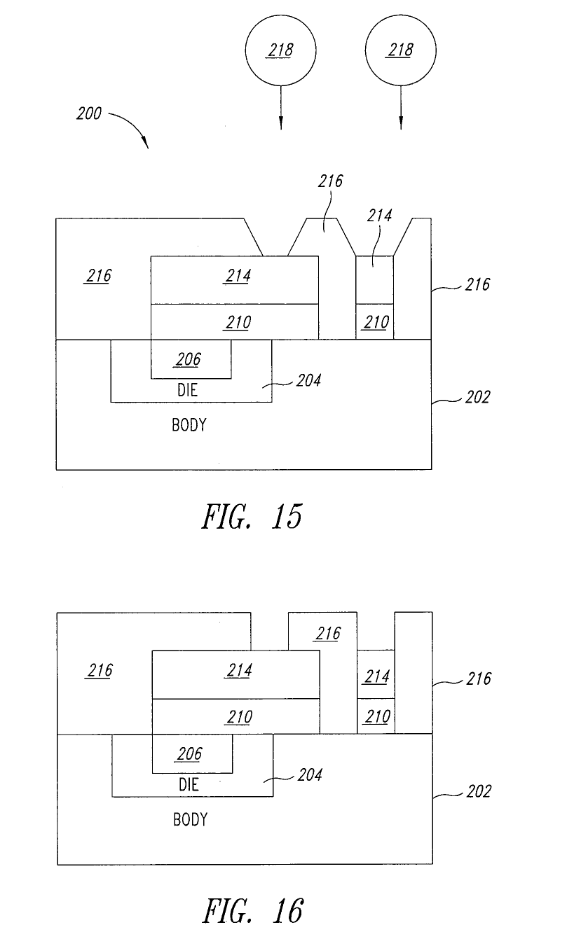

FIG. 15 shows an embodiment of an array 200 with a dielectric material 216 patterned and positioned on the conductive plating 214. In some embodiments, such as the embodiment illustrated in FIG. 15, the dielectric material 216 may be patterned so as to form contact pads to which solder balls 218 may be applied.

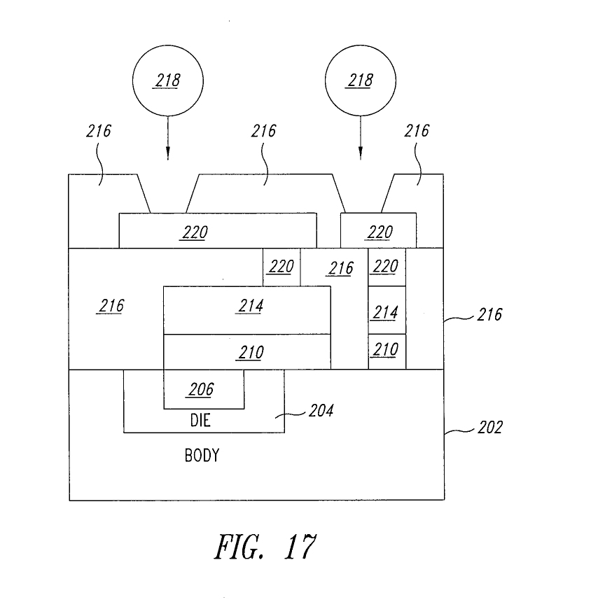

FIG. 16 shows an embodiment of an array 200 with a first dielectric material 216 patterned and positioned on the conductive plating 214 to form regions for positioning additional regions of conductive material, such as additional copper regions, etc. Additional processes, such as additional photo-resist and patterning, barrier layer deposition, conductive region plating, photo-resist striping, barrier layer etching, etching to remove barrier layer etchant, etc., from the conductive regions, and dielectric region formation may be employed in some embodiments. See FIGS. 11 through 16.

FIG. 17 shows an embodiment of an array 200, such as the embodiment of FIG. 16, after one or more of the processes illustrated in FIGS. 11 through 16 have been repeated to form multiple additional conductive regions 220 to form multi-layer conductive redistribution layers/contact pads to which solder balls 218 may be applied.

Embodiments of methods of manufacturing semiconductor devices such as embedded wafer-level ball grid arrays, may employ additional steps, layers, regions and processes, etc., may omit steps, layers, regions, processes, etc., and may perform steps and processes in various orders. For example, additional photo-resist processes, additional barrier regions, stop-etch layers or regions or sacrificial layers and regions may be employed in some embodiments. In another example, in some embodiments another material may be applied to the plurality of conductive regions during subsequent processing to avoid leaving the conductive regions exposed. For example, metal or metal alloys such as copper, nickel, gold, other metals and alloys, etc., may be applied to one or more or conductive regions such as conductive pads. For example, a layer of nickel, for example on the order of 300 to 800 Angstroms in thickness, and a layer of gold, on the order of 30 Angstroms in thickness, may be applied to the conductive regions or pads in some embodiments. In another example, solder balls may be applied to one or more conductive regions, such as copper pads, etc., and may be applied after the application of additional layers to the conductive regions.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a dielectric region on a substrate, the dielectric region having a plurality of channels in a first surface of the dielectric region;
forming a barrier region of a first conductive material on the first surface of the dielectric region and on surfaces of the plurality of channels of the dielectric region;
forming a conductive region of a second conductive material different from the first conductive material on the barrier region;
removing part of the conductive region to form a plurality of conductive pads of the second conductive material in the plurality of channels;
removing portions of the barrier region on the first surface of the dielectric region using a first etchant; and
subsequently etching surfaces of the plurality of conductive pads of the second conductive material to remove the first etchant from surfaces of the plurality of conductive pads.

2. The method of claim 1, further comprising forming a plurality of components in a substructure of the substrate, wherein forming the dielectric region comprises forming a dielectric layer on the substructure and forming channels through the dielectric layer to components of the plurality of components.

3. The method of claim 1 wherein the first conductive material comprises titanium tungsten and the second conductive material comprises copper.

4. The method of claim 1 wherein removing part of the conductive region to form a plurality of conductive pads of the second conductive material in the plurality of channels comprises etching the conductive region.

5. The method of claim 1 wherein the first etchant comprises hydrogen peroxide.

6. The method of claim 5 wherein etching surfaces of the plurality of conductive pads of the second conductive material comprises removing traces of the hydrogen peroxide and hydrogen peroxide byproducts from surfaces of the plurality of conductive pads.

7. The method of claim 1, further comprising assembling an integrated circuit package including the substrate.

8. The method of claim 1 wherein the plurality of conductive pads of the second conductive material comprise a plurality of conductive pads of a semiconductor package ball-grid array.

9. The method of claim 1 wherein subsequently etching surfaces of the plurality of conductive pads of the second conductive material comprises using at least one etchant selected from the group including: cupric chloride; ferric chloride; ammonium sulfate; ammonia; nitric acid; and hydrochloric acid.

10. The method of claim 1, further comprising:
subsequently forming a plurality of conductive regions of a third conductive material on at least some of the plurality of conductive pads of the second conductive material, wherein the third conductive material is different from the second conductive material.

11. The method of claim 10 wherein the plurality of conductive regions of a third conductive material comprise a plurality of solder balls.

12. The method of claim 10 wherein the third conductive material comprises at least one of nickel and gold.

13. A method, comprising:
forming a barrier region of a first conductive material on a substrate;
forming a first plurality of conductive regions of a second conductive material, each region of the first plurality of conductive regions of the second conductive material having a first surface on the barrier region and a second surface opposite of the first surface;
etching portions of the barrier region between the first plurality of conductive regions of the second conductive material using a first etchant; and
subsequently etching at least the second surfaces of the first plurality of conductive regions of the second conductive material to remove the first etchant from at least the second surfaces of the first plurality of conductive regions.

14. The method of claim 13 wherein forming the barrier region comprises forming a barrier layer having a plurality of channels and forming the first plurality of conductive regions of the second conductive material comprises forming conductive regions of the second conductive material in the plurality of channels of the barrier layer.

15. The method of claim 13 wherein the first conductive material comprises titanium tungsten and the second conductive material comprises copper.

16. The method of claim 13 wherein the first plurality of conductive regions of the second conductive material comprise a plurality of conductive pads.

17. The method of claim 13 wherein the first plurality of conductive regions of the second conductive material comprise a plurality of conductive traces.

18. The method of claim 13 wherein the first plurality of conductive regions of the second conductive material comprise a plurality of conductive pads and a plurality of conductive traces.

19. The method of claim 13, further comprising forming a second plurality of conductive regions on at least some of the second surfaces of the first plurality of conductive regions.

20. The method of claim 19 wherein the second plurality of conductive regions comprise the second conductive material.

21. The method of claim 20 wherein at least some of the second plurality of conductive regions comprise redistribution layers.

22. A semiconductor device, comprising:
a wafer having a plurality of die; and
a first plurality of conductive regions separated by at least one dielectric region, each of the first plurality of conductive regions having:
a barrier region on the wafer; and
a copper region having at least a first surface on the barrier region and a second surface opposite of the first surface, wherein an oxidation thickness of the second surface of the copper region is less than 100 nanometers.

23. The semiconductor device of claim 22 wherein the first plurality of conductive regions comprise a plurality of conductive pads of a ball-grid array.

24. The semiconductor device of claim 22 wherein the oxidation thickness of the second surface of the copper region is less than 10 nanometers.

25. The semiconductor device of claim 22 wherein the first plurality of conductive regions comprise a plurality of redistribution layers, the semiconductor device further comprising:
a second plurality of conductive regions on at least some of the plurality of redistribution layers.

26. The semiconductor device of claim 25 wherein the second plurality of conductive regions comprise copper bonding pads.
